(19) United States
(12) Patent Application Publication
(10) Pub. No.: US 2025/0349355 A1
(43) Pub. Date: Nov. 13, 2025

(54) ONE-WIRE SERIAL INTERFACE FOR LOW-BIT-COUNT PROGRAMMABLE RESISTIVE MEMORY

(71) Applicant: Attopsemi Technology Co, LTD, Hsinchu City (TW)

(72) Inventors: Shine C. Chung, San Jose, CA (US); TE LOU, Taipei City (TW)

(73) Assignee: Attopsemi Technology Co, LTD, Hsinchu City (TW)

(21) Appl. No.: 18/657,741

(22) Filed: May 7, 2024

(51) Int. Cl. G11C 13/00

(52) U.S. Cl. CPC G11C 13/0069; G11C 13/004; G11C 13/0061

(57) ABSTRACT

A one-wire serial interface that provides a control signal CNTL with 3-level logic to access at least one low-bit-count programmable resistive memory. The one-wire CNTL has three levels, such as VDD, VDD/2, and VSS (0V), to generate clock and data signals for serial communication. In doing so, the one-wire serial interface can use at least one of various procedures including: quantization, de-glitch, logic mapping, state-memorized logic, and pass code.

### BACKGROUND OF THE RELATED ART

Programmable resistive memory is a kind of non-volatile memory that the program or unprogrammed state is determined by resistance difference. The non-volatile memory is able to retain data when the power supply of the memory is cut off. The memory can be used to store permanent data such as parameters, configuration settings, long-term data storage, etc. Similarly, this kind of memory can be used to store instructions, or codes, for microprocessors, DSPs, or microcontrollers (MCU), etc. Programmable resistive memory normally has three operations, read, write (or called program), and erase, if applicable, for reading data, programming data, and erasing data before re-programming. Programmable resistive memory can be an EPROM, EEPROM, or flash memory that can be programmed from 10K to 100K times, or Multiple-Time Programmable (MTP) to be programmed from a few times to a few hundred times, or One-Time Programmable (OTP) to be programmed one time only. The programmable resistive memory can also be emerging memories such as PCRAM (Phase Change RAM), RRAM (Resistive RAM), FRAM (Ferroelectric RAM), or MRAM (Magnetic RAM).

One-Time-Programmable (OTP) is a particular type of programmable resistive memory that can be programmed only once. An OTP memory allows the memory cells being programmed once and only once in its lifetime. OTP is generally based on standard CMOS processes and is usually embedded into an integrated circuit that allows each die in a wafer to be customized. There are many applications for OTP, such as memory repair, device trimming, configuration parameters, chip ID, security key, feature select, and PROM, etc.

FIG. 1(a) shows a conventional programmable resistive cell 10, which is well suited for a low-bit-count programmable resistive memory. The programmable resistive memory cell 10 has a programmable resistive element 11 and a program selector 12. The programmable resistive element 10 is coupled to a supply voltage V+ at one end and to a program selector 12 at the other end. The program selector 12 has the other end coupled to a second supply voltage V−. The program selector 12 can be turned on by asserting a control terminal Sel. The program selector 12 is usually constructed from a MOS device. The programmable resistive element 11 is usually an electrical fuse based on polysilicon, silicided polysilicon, metal, thermally isolated semiconductor region, a floating gate to store charges, or an anti-fuse based on gate oxide breakdown, etc.

FIG. 1(b) shows another programmable resistive cell 15. The programmable resistive cell 15 has a programmable resistive element 16 and a diode as a program selector 17. The programmable resistive element 16 is coupled to a supply voltage V+ at one end and a program selector 17 at the other. The program selector 17 has the other end coupled to a second supply voltage V− as a select signal Sel. It is desirable for the program selector 17 to be fabricated in CMOS compatible processes. The program selector 17 can be constructed from a diode that can be embodied as a junction diode with at least one P+ active region on an N well, or a diode with P+ and N+ implants on two ends of a polysilicon substrate or active region on an insulated substrate. The programmable resistive element 16 is commonly an electrical fuse based on polysilicon, silicided polysilicon, metal, CMOS gate material, or anti-fuse based on gate oxide breakdown.

FIG. 2 shows a block diagram of a typical low-bit-count programmable resistive cell 30 for a low-bit-count programmable resistive memory. The programmable resistive cell 30 has one programmable resistive element 31 coupled to a supply voltage VDDP at one end and to a selector 32 at the other end as Vx. The selector 32 can be enabled by asserting a signal Sel. The node Vx can be coupled to a sense amplifier 33 and then to a latch 34 by a read signal RE. For low-bit-count programmable resistive memories, there can be some advantages to build a sense amplifier and a latch into each cell to save the overall costs in a macro and for ease to use.

For a typical low-bit-count programmable resistive memory, there are lots of control signals, other than VDD, supply voltage, VDDP, power supply voltage, and VSS (ground, or 0V), such as Clock CK, program enable PGM, read enable READ, and address signals to select any cell. Conventional low-bit-count programmable resistive memory use only two signals for read and program, such as SCK (serial clock) and SDA (serial data) in an I2C serial interface. By using these two signals, serial communication protocol can be established, such as frames of device ID, command (R/W), address, data, and acknowledge bits, etc.

FIG. 3 shows a portion of a block diagram 40 of a one-wire interface between a bus master 47 (initiator) and a bus slave 48 (responder) in a low-bit-count programmable resistive memory. For example, one example of such a low-bit-count programmable resistive memory is a 1-wire EEPROM, such as a DS28E07 EEPROM chip from Analog Devices, Inc. The bus master 47 has a receiver 43 and a transmitter 42 coupled to a 1-wire bus 49. Similarly, the bus slave 48 has a receiver 44 and a pulldown MOS 45 as a transmitter coupled to the same 1-wire bus 49. This 1-wire serial communication protocol has a pullup resistor 41 coupled to VPDP, or VDD, at one end and the 1-wire bus 49 at the other. This protocol is based on precision timing protocol between the bus master 47 and the bus slave 48. For example, the bus master 47 sends a reset pulse to the 1-wire bus 49 for 480 us and then releases. The bus slave 48 needs to respond by pulling down the 1-wire bus 49 for 60 us to show “presence,” otherwise no bus transaction happens. To send a data 1 and 0, the bus master 47 needs to send a brief 1-15 us and 60 us low pulse, respectively. The falling edge of the pulse can be used to start a monostable multivibrator in the bus slave 48 to read the data about 30 us after the falling edge pulled low by the bus master 47. To receive data, the bus master 47 sends a 1-15 us low pulse to start each bit. If the bus slave 48 wants to send a “1”, it does nothing, and the 1-wire bus 49 goes to pullup voltage VPDP. If the bus slave 48 wants to send a 0, it pulls the 1-wire bus 49 low for 60 us.

FIG. 4 shows a bit encoding scheme 60 using Manchester code for one-wire communication. The timing waveform 60 shows four bits, 61, 62, 63, and 64 to represent data 0, 1, 0, and 1, respectively. Each bit has one high/low transition, namely, high-to-low for data 0 and low-to-high for data 1. The bus can be driven by master and slave with tri-state buffers and with precision timing protocols agreed upon between the master and slave, similar to those shown in FIG. 3.

The one-wire serial communication approach in FIG. 3 or 4 are complicated, hard to implement by VLSI, and consume lots of silicon area. Thus, there is a need for improved approaches to provide serial communications over one wire for use with low-bit-count programmable resistive memories.

### SUMMARY

The invention relates to a low-bit-count programmable resistive memory and a serial interface that is based on only one wire, other than VDD and VSS, for read, program, and soft program, etc. For example, in one embodiment, a low-bit-count programmable resistive memory can have any bit counts, such as from one (1) bit to thirty-two (32) bits, and can also be cascadable for more memory.

The invention can be implemented in numerous ways, including as a method, system, device, or apparatus (including graphical user interface and computer readable medium). Several embodiments of the invention are discussed below.

As a programmable resistive memory integrated in an integrated circuit, one embodiment can, for example, include at least: at least one 1-wire serial interface block; and at least one programmable resistive memory block, the at least one programmable resistive memory block including at least: a plurality of programmable resistive cells. At least one of the plurality of programmable resistive cells can include at least: a programmable resistive element (PRE) having one end coupled to a first supply voltage line; a selector having at least a first active region and a second active region, the first active region having a first type of dopant and a second active region having the first type or a second type of dopant, the first active region providing a first terminal of the selector, the second active region providing a second terminal of the selector, both the first and second active regions built on a semiconductor material or insulator substrate, the first active region coupled to the programmable resistive and the second active region coupled to a second supply voltage line; and a gate fabricated on the layer of the semiconductor or metal material with a sandwich of dielectric in between configured to divide into the first and the second active regions, the gate coupled to a third supply voltage line. The PRE can be configured to be programmable by applying voltages to the first, second, and/or the third supply voltage lines to thereby change its logic state with the control signals generated from the 1-wire serial interface block.

As an electronics system, one embodiment can, for example, include at least: a processor; and at least one programmable resistive memory. The at least one programmable resistive memory can, for example, include at least: at least one 1-wire serial interface block; and at least one programmable resistive memory block, the programmable resistive memory block operatively connected to the processor, the programmable resistive memory block including at least a plurality of programmable resistive cells. At least one of the plurality of programmable resistive cells can include at least: a programmable resistive element (PRE) having one end coupled to a first supply voltage line; a selector having at least a first active region and a second active region, the first active region providing a first terminal of the selector, the second active region providing a second terminal of the selector, the first active region coupled to the PRE and the second active region coupled to a second supply voltage line; and a gate configured to divide into the first active region and the second active region, the gate coupled to a third supply voltage line. The PRE can be configured to be programmable by applying voltages to the first, second, and/or the third supply voltage lines to thereby change its logic state with the control signals generated from the 1-wire serial interface block.

As a method for providing a 1-wire interface to recover clock and data signals for at least one programmable resistive memory in an integrated circuit, one embodiment can, for example, include at least: receiving a 3-level control signal; converting the 3-level control signal into determine clock and data signals based on first and second thresholds, respectively; filtering out noise from the determined clock and data signals; modifying the determined clock signal or the determined data signal to apply a state-memorized effect; and subsequently using the determined clock signal and the determined clock signal for serial communication.

### BRIEF DESCRIPTION OF THE DRAWINGS

The present invention will be readily understood by the following detailed descriptions in conjunction with the accompanying drawings, wherein like reference numerals designate like structural elements, and in which:

FIG. 1(a) shows a conventional programmable resistive cell that has one programmable resistive element and one MOS as program selector.

FIG. 1(b) shows a conventional programmable resistive cell that has one programmable resistive element and one diode as program selector.

FIG. 2 shows a conventional low-bit-count programmable resistive cell that has one programmable resistive element, one program selector, a sense amplifier, and a latch.

FIG. 3 shows block diagram of a one-wire serial interface using open drain circuits with a pullup resistor.

FIG. 4 shows a timing waveform of a Manchester coding for another one-wire serial interface.

FIG. 5(a) shows a block diagram of programmable resistive memory block using one external wire for serial interface.

FIG. 5(b) shows a block diagram of programmable resistive memory and a 1-wire interface block with a POR.

FIG. 6 shows a portion of a timing waveform to recover clock and data from a one-wire signal, corresponding to the block diagram in FIG. 5(b).

FIG. 7 shows a portion of a block diagram to recover clock and data from a one-wire signal, corresponding to the timing waveform in FIG. 6.

FIG. 8(a) shows a schematic of a highly skewed inverter as quantizer.

FIG. 8(b) shows a schematic of a stacked inverter using core devices and core voltage clamp, according to another embodiment of quantizer.

FIG. 9(a) shows a portion of a clock and data timing waveform after quantization.

FIG. 9(b) shows a porting of the desirable clock and data timing waveform after quantization, de-glitch, logic mapping, and SR-latch.

FIG. 9(c) shows a table for clock and data logic mapping after quantization.

FIG. 9(d) shows a portion of schematic of logic mapping and SR latch to generate desirable data.

FIG. 10(a) shows a portion of a block diagram of serial communication frame such as device ID, command, address and data bytes after recovering clock and data.

FIG. 10(b) shows a portion of a block diagram of simplified serial communication frame such as device ID, command, and data bytes after recovering clock and data.

FIG. 11(a1) shows a timing waveform of VDD and POR upon VDD ramping.

FIG. 11(a2) shows a portion of a block diagram of reading at least one of the programmable resistive cells after a POR is generated.

FIG. 11(a3) shows a portion of a block diagram of relaxation oscillation, corresponding to FIG. 11(a2), according to one embodiment.

FIG. 11(b) shows a timing waveform of programming programmable resistive cells after clock and data are recovered.

FIG. 11(c) shows a timing waveform of soft programming programmable resistive cells after clock and data are recovered.

FIG. 12(a) shows a portion of a layout to place a one-wire interface pad and at least one low-bit-count programmable resistive memory in an I/O ring, according to one embodiment.

FIG. 12(b) shows a portion of a layout to place a one-wire interface pad and at least one low-bit-count programmable resistive memory in an I/O ring, according to another embodiment.

FIG. 13(a) shows a flow chart of a read procedure for a low-bit-count programmable resistive memory upon power ramping, according to one embodiment.

FIG. 13(b) shows a flow chart of recovering clock and data from a one-wire signal for a low-bit-count programmable resistive, according to another embodiment.

FIG. 14 shows a processor electronic system that employees at least one low-bit-count programmable resistive memory with a 1-wire interface block according to one embodiment.

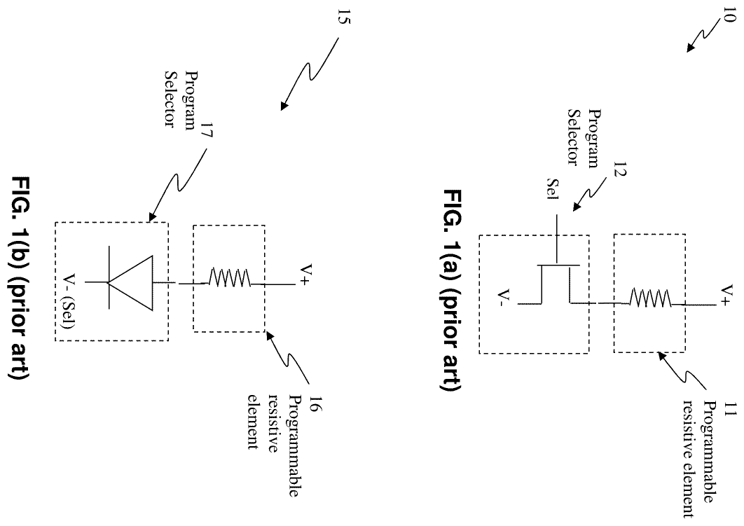

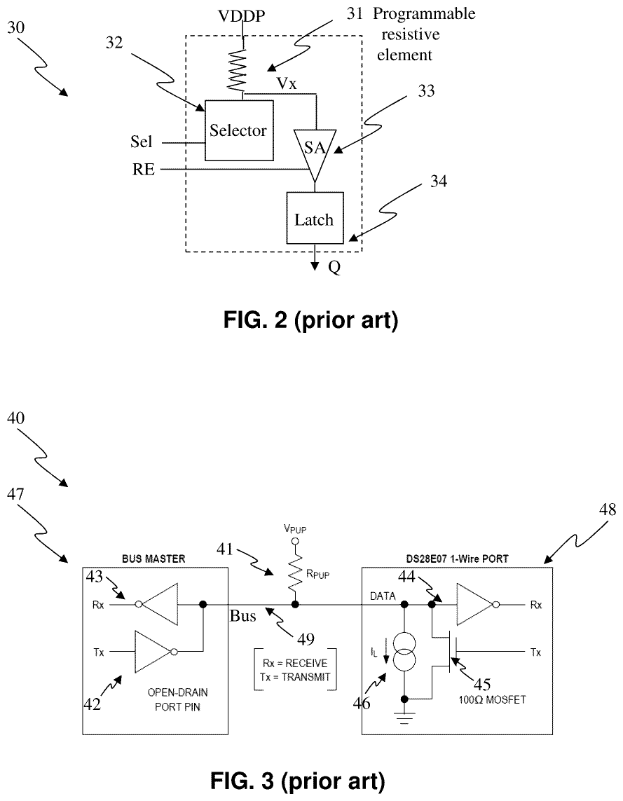

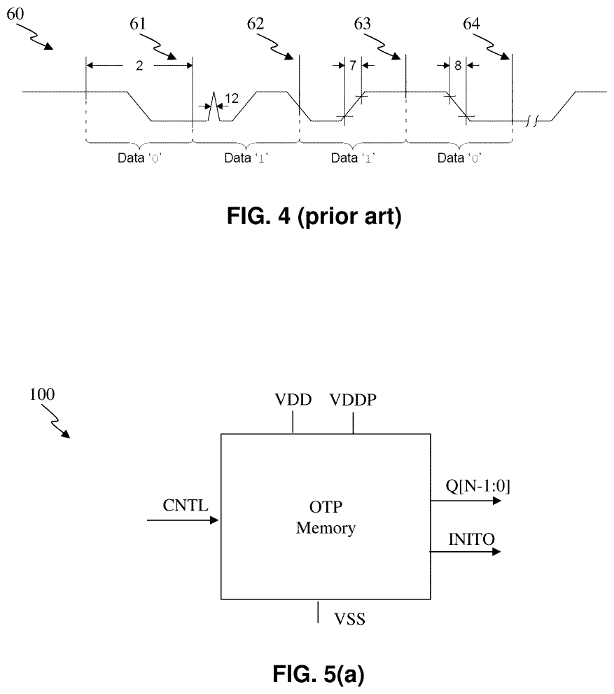

### DETAILED DESCRIPTION OF THE INVENTION

The invention relates to a programmable resistive memory having one wire for serial communication. The programmable resistive memory typically has a low bit count, such as having a data storage capacity of less than 256 bits (e.g., 8, 16, 32, 64, 128 or 256 bits). In one embodiment in architecture, the low-bit-count programmable resistive memory has memory bit cells that include a programmable resistive element (PRE), program selector, reference resistance, sense amplifier and latch to store data. Reading one, a group of OTP cells, or all can be achieved by generating a POR (Power-on Reset) upon power ramping up. The POR can go through at least one of the procedures to enable a dummy sense amplifier (SA) to start relaxation oscillation to generate a read clock and then to start a counter to generate read addresses. At least one normal SA can be enabled by the read clock to sense at least one of the PRE resistance cells selected by the read address and to store the data into a latch. A 3-level (VDD, VDD/2,0V) one-wire signal can be used to recover clock and data so as to start at least one serial communication frames, such as device ID, command, address, and data etc. The command can include at least one of the program or soft program to change the PRE resistance or load data into a latch in the cell, respectively. The programmable resistive cells can be accessed randomly or sequentially, or through shift registers.

In one embodiment, a memory cell of a low-bit-count programmable resistive memory can be triggered by a POR (Power-On Reset) during VDD ramping to enable a dummy sense amplifier (SA). The dummy SA can trigger a relaxation oscillation and then start a counter to generate a read clock and read addresses. Normal SA can sense at least one programmable resistive cell selected by the read address and enabled by the read clock and stored the logic state in a latch. A 3-level logic CNTL can be used for serial communication by recovering clock and data first, and then to start serial communication frames. Clock/data recovery can be through at least one of quantization, de-glitch, logic mapping, and state-memorized logic, such as SR-latch (Set/Reset-latch) or the like, and pass code. The recovered clock and data can start at least one of the serial communication frames, such as device ID, command, address, and data, etc. The commands in a serial communication can be programming, soft programming, or erasing if applicable. Programming at least one of the programmable resistive cells into a different resistance can be achieved to the at least one cell selected by an address and enabled by a clock under a PGM command. Soft programming, loading data into a cell latch for testing before actual programming, to at least one programmable resistive cell can be achieved to the at least one cell selected by an address and enabled by a clock under a SPGM command. The accesses on the at least one programmable resistive cell can be sequential, random or through shift registers.

In another embodiment, a low-bit-count programmable resistive memory can read data based on a POR, Power-On Reset, generated during VDD ramping. The POR can enable a dummy SA to trigger a relaxation oscillation to generate read clock and then to start a counter to generate read addresses. The selected programmable resistive cell can be read by at least one normal SA enabled by read clock one or a group of cells at a time. A 3-level logic CNTL can be used for serial communication by recovering clock and data first, and then to start serial communication frames. Clock/data recovery can be through at least one of quantization, de-glitch, logic mapping, and state-memorized logic, such as SR-latch or the like, and pass code. The recovered clock and data can start at least one of the serial communication frames, such as device ID, command, address, and data, etc. The commands in a serial communication can be programming, soft programming, or erasing if applicable. Programming at least one of the programmable resistive cells into a different resistance can be achieved to the at least one cell selected by an address and enabled by a clock under a PGM command. Soft programming, loading data into a cell latch for testing before actual programming, to at least one programmable resistive cell can be achieved to the at least one cell selected by an address and enabled by a clock under a SPGM command. The accesses on the at least one programmable resistive cell can be sequential, random or through shift registers.

As a low-bit-count programmable resistive memory, one embodiment can, for example, include a plurality of programmable resistive cells. At least one of the programmable resistive cells can include a programmable resistive element (PRE) coupled to a selector. Reading a programmable resistive cell can be triggered by generating a POR during VDD ramping or rising a READ signal. The POR can enable a dummy SA to start a relaxation oscillation to generate a read clock and then start a counter to generate read addresses. Normal SA can sense at least one of the PRE resistances selected by an address and enabled by a read clock and store the logic state into a latch. This low-bit-count programmable resistive memory has a one wire interface block using 3-level logic for program, soft program (loading data into cell latches for testing before actual programming), and erase if applicable. This can be achieved by recovering a clock and data from this wire to start serial communication frames. The clock/data recovery can go through at least one of the steps of quantization, de-glitch, logic mapping, state-memorized logic (such as SR latch), and pass code to generate clock and data. The serial clock and data, once available, can start at least one of the serial communication frames, such as device ID, command, address, and data, etc. Programming at least one of the programmable resistive cells into a different resistance can be achieved to the at least one cell selected by an address and enabled by a clock under a PGM command. Soft programming, loading data into a cell latch for testing before actual programming, to at least one programmable resistive cell can be achieved to the at least one cell selected by an address and enabled by a clock under a SPGM command. The program or soft program operations on the at least one programmable resistive cell can be sequential, random or through shift registers.

As an electronics system, one embodiment can, for example, include at least a processor, a 1-wire interface block, and a low-bit-count programmable resistive memory operatively connected to the processor. At least one of the programmable resistive cells can include a programmable resistive element (PRE) coupled to a selector. Reading a programmable resistive cell can be triggered by generating a POR during VDD ramping. The POR can enable a dummy SA to start a relaxation oscillation to generate a read clock and then start a counter to generate read addresses. Normal SA can sense PRE resistance selected by the read address and enable by the read clock and store the logic state into a latch. This low-bit-count programmable resistive memory has a one-wire interface block using 3-level logic for program, soft program (loading data into cell latches for testing before actual programming), and erase if applicable. This can be achieved by recovering a clock and data from this wire to start serial communication frames. The clock/data recovery can go through at least one of the steps of quantization, de-glitch, logic mapping, state-memorized logic (such as SR latch), and pass code to generate clock and data. The serial clock and data, once available, can start at least one of the serial communication frames, such as device ID, command, address, and data, etc. Programming at least one of the programmable resistive cells into a different resistance can be achieved to the at least one cell selected by an address and enabled by a clock under a PGM command. Soft programming, loading data into a cell latch for testing before actual programming, to at least one programmable resistive cell can be achieved to the at least one cell selected by an address and enabled by a clock under a SPGM command. The program or soft program operations on the at least one programmable resistive cell can be sequential, random or through shift registers.

As a method for providing a 1-wire interface for a low-bit-count programmable resistive memory, one embodiment can, for example, include at least providing a plurality of programmable resistive cells. At least one of the programmable resistive cells can include a programmable resistive element coupled to a selector. Reading a programmable resistive cell can be triggered by generating a POR during VDD ramping. The POR can enable a dummy SA to start a relaxation oscillation to generate a read clock and then start a counter to generate read addresses. Normal SA can sense at least one of the PRE resistances selected by the read address and enabled by the read clock and store the logic state into a latch. A one-wire signal CNTL, with 3-level logic, can be used for programming, soft programming (loading data into cell latches for testing before actual programming), and erasing if applicable. This can be achieved by recovering a clock and data from this wire to start serial communication frames. The method to recover clock/data can go through at least of one of the steps of quantization, de-glitch, logic mapping, state-memorized logic (such as SR latch), and pass code to generate clock and data. The serial clock and data, once available, can start at least one of the serial communication frames, such as device ID, command, address, and data, etc. Programming at least one of the programmable resistive cells into a different resistance can be achieved to the at least one cell selected by an address and enabled by a clock under a PGM command. Soft programming, loading data into a cell latch for testing before actual programming, to at least one programmable resistive cell can be achieved to the at least one cell selected by an address and enabled by a clock under a SPGM command. The program or soft program operations on the at least one programmable resistive cell can be sequential, random or through shift registers.

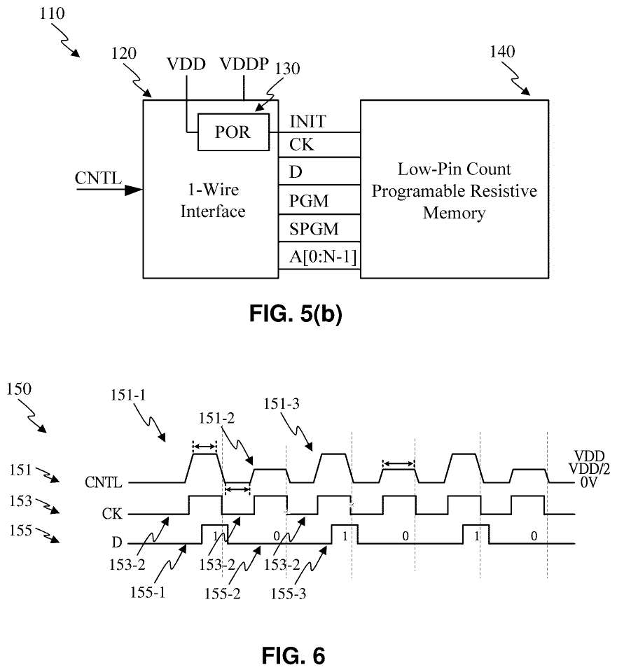

FIG. 5(a) shows a block diagram of a low-bit-count programmable resistive memory block 100 that have core supply voltage VDD, program supply voltage VDDP, and ground VSS. A 3-level signaling CNTL can be used to recover clock and data for serial communication. Reading one, a group of cells, or all cells can be enabled by an INIT, triggered by a POR (Power-On Reset) generated during VDD ramping. The Q[N-1:0] are the data in the latches for output. An INITO signal can be asserted after finishing read, program, or soft program operations on this macro and to trigger working on the next macros in a daisy-chain fashion.

FIG. 5(b) shows a block diagram of a low-bit-count programmable resistive memory block 110, corresponding to 100 in FIG. 5(a), according to one embodiment. The block 110 has a 1-wire interface block 120 that includes a POR block 130, and a low-bit-count programmable resistive memory 140. The POR 130 in the 1-wire interface block 120 generates an INIT signal to read one or all cells of the programmable resistive memory 140 into latches. The 1-wire interface block 120 can also generate clock, command, data, and address signals, such as CK, PGM, SPGM, D, and A[0:N-1], respectively, to access the programmable resistive memory 140.

FIG. 6 shows a portion of a timing waveform 150 of a 3-level signal CNTL 151 to generate the desirable clock CK 153 and data D 155. The 3-level signal CNTL 151 has VDD, VDD/2, and 0V logic levels that can be used to recover CK and D from this signal CNTL 151 for serial communication. CNTL 151 has the first 3 cycles 151-1, 151-2, and 151-3 to represent CK=1/D=1, CK=1/D=0, and CK=1/D=1, respectively. CNTL 151 should generate CK=1 for the first 3 cycles, 153-1, 153-2, and 153-3. Similarly, CNTL 151 should generate D=1, D=0, and D=1 for the first 3 cycles 155-1, 155-2, and 155-3, respectively. The falling edges of D 155-1 and 155-3 can be extended beyond the CK falling edges of 153-1 and 153-3 so that D can be strobed as 1 in the first and third cycles at the falling edges of CK. The CNTL can have the 3 levels of approximately full (100%), half (50%) and 0V of a core or I/O supply voltage in one embodiment. The CNTL can also have the 3 levels of approximately full IO voltage VDD, full core voltage VDDC, and 0V in another embodiment.

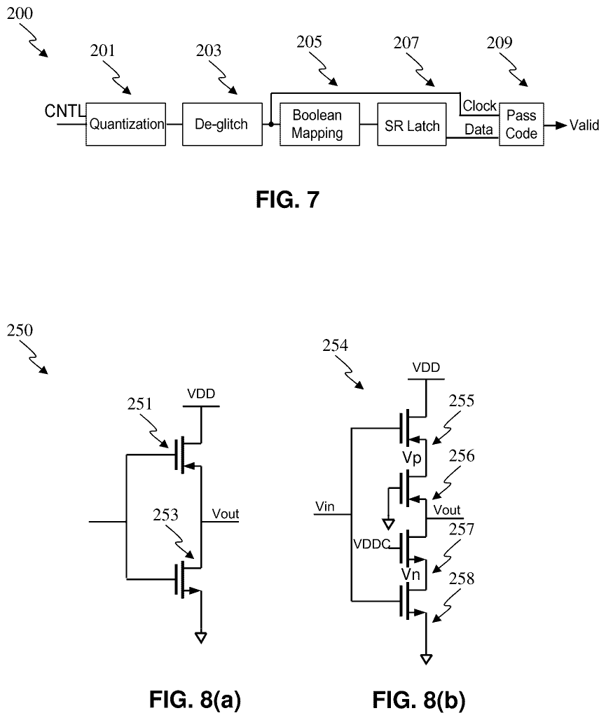

FIG. 7 shows a portion of block diagram of a signal recovery procedure 200 to recover the desirable clock CK and data D from a 3-level signal CNTL, according to one embodiment. The signal recovery procedure 200 can, for example, be used to recover the clock CK and data D from the timing waveform in FIG. 6. The signal recovery procedure 200 can include at least quantization 201, de-glitch 203, logic mapping 205 (e.g., Boolean mapping), and state-memorized logic 207 (e.g., SR-latch), and pass code 209. The quantization 201 converts the 3-level signal CNTL with quantization levels near to Vtn and VDD-|Vtp| to generate raw clock and data, respectively. The de-glitch block 203 filters any glitches to ensure more robust operations. In one embodiment, the de-glitch block 203 can be implemented as a delay chain to provide 5 ns˜10 n delay to filter out any glitches. In another embodiment, the de-glitch block 203 can be implemented as a two-input AND gate from a signal and the same polarity of the signal with more delays to remove glitches. The logic mapping block 205 can re-arrange Boolean functions so that the state-memorized logic 207 can be applied to keep the previous data when the waveform transits from CK=1/D=0 to CK=1/D=1. The state-memorized logic 207 can output a new data D to extend the falling edge beyond CK that can be combined with the previous CK as a pair of clock and data for further serial communication. The pass code block 209 is to detect a specific code, such as a 4-7 bit code (e.g., 1010101), to validate a serial transmission and to prevent false communication.

FIG. 8(a) shows a schematic of an inverter 250 as a quantizer, according to one embodiment. For example, the inverter 250 can be used to implement the quantizer 201. PMOS 251 has a gate, source, and drain coupled to input Vin, VDD, and Vout, respectively. NMOS 253 has a gate, source, and drain coupled to input Vin, VSS (ground), and Vout, respectively. The inverter 250 can have sizes, Wn/Ln/(Wp/Lp)<<1 to generate raw data D for further processing. Similarly, the inverter 250 can have sizes, Wn/Ln/(Wp/Lp)>>1 to generate raw clock CK for further processing. The VDD often needs to be larger than 3× of Vtn or |Vtp|.

FIG. 8(b) shows a stacked inverter 254 using all core devices as a quantizer, according to another embodiment. For example, the inverter 254 can be used to implement the quantizer 201. Core devices have lower Vtn or |Vtp| so that the 3× rule noted above with respect to FIG. 8(a) can be easier to satisfy. Core supply voltage VDDC is used to clamp a core NMOS device 257 to prevent high voltage applied to the core device 257. PMOS device 255 has a gate, source, and drain coupled to the input Vin, VDD, and an intermediate node Vp, respectively. Another PMOS device 256 has a gate, source, and drain coupled to VSS (ground), Vp, and Vout, respectively. NMOS device 258 has a gate, source, and drain coupled to the input Vin, VSS, and an intermediate node Vn, respectively. Another NMOS device 257 has a gate, source, and drain coupled to core supply voltage VDDC, Vn, and Vout, respectively. The NMOS device 258 and the PMOS device 255 can have sizes, Wn/Ln/(Wp/Lp)<<1 to generate a raw data D for further processing. Similarly, the NMOS device 258 and the PMOS device 255 can have sizes, Wn/Ln/(Wp/Lp)>>1 to generate a raw clock CK for further processing. The PMOS device 256 and the NMOS device 257 are used to clamp high voltages so as to protect core device, namely, the NMOS device 258 and the PMOS device 255 from a high voltage being applied.

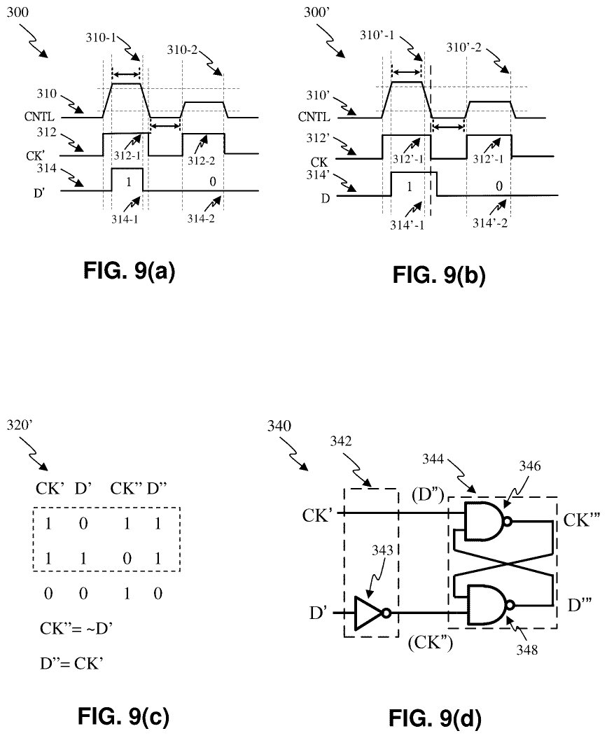

FIG. 9(a) shows a portion of timing waveform of a 3-level CNTL 300 after quantization to generate raw clock CK′ 312 and raw data D′ 314, according to the timing waveform in FIG. 6 and the quantizer in FIG. 8(a) or 8(b). The quantizer with a smaller Wp/Lp to Wn/Ln ratio operates on the 3-level CNTL 300 and generates a raw clock CK′ 312 with 312-1 and 312-2 representing the first and second clocks pulses thereof, respectively. Similarly, the quantizer with a larger Wp/Lp to Wn/Ln ratio operates on the 3-level CNTL 300 and generates a raw data D′ 314 with 314-1 and 314-2 representing data 1 and 0 in the first two cycles thereof, respectively.

In FIG. 9(a), data D′ pulse 314-1 is within the clock CK' pulse 312-1 that cannot be strobed as 1 at the CK′ falling edge. FIG. 9(b) shows a portion of a desirable timing waveform 300′ that has CNTL 310′ to generate a desirable clock CK 312′ and data D 314′ based on the raw clock CK′ 312 and data D′ 314 in FIG. 9(a). The clock CK 312′ and the data D 314′ in FIG. 9(b) are the final waveform after the clock and data are recovered from the CNTL 310′, corresponding to the outputs of the block 203 and 207 in FIG. 7. The first two cycles of CNTL 310′ are 310′-1 and 310′-2 and the first two cycle of data D′ 314 are 314′-1 and 314′-2 to indicate the desirable clock and data waveform for 1 and 0, respectively. The falling edge of D 314′-1 is extended beyond the falling edge of the clock CK 312′-1 so that the D can be strobed as a 1 at the falling edge of CK 312′-1.

In FIG. 9(b), the final data D needs to be modified to remain high to ensure proper operation when transiting from CK′=1/D′=1 to CK′=1/D′=0 in the quantizer output. In one embodiment, CK′=1 and D′=0 can be mapped to CK″=1 and D″=1 so that a following state-memorized logic, such as SR-latch, can keep the same data for D″ during state transiting from CK′=1/D′=1 to CK′=1/D′=0.

FIG. 9(c) shows a table for the logic mapping, such as for use by the logic mapping block 205. After applying a logic mapping CK″ =˜D′ and D″=CK′, the data can keep the same high value when states transit from CK′=1/D′=1 to CK′=1/D′=0 in an output of an SR-latch.

FIG. 9(d) shows a portion of a schematic 340 of logic mapping 342 with a SR-latch 344, corresponding to FIGS. 9 (a)-9(c). The logic mapping block 342 uses CK′ for D″ and inverted D′ for CK″ as input to a follow-on SR-latch 344. The SR-latch 344 has two cross-coupled NAND devices 346 and 348, with two inputs D″ and CK″, to generate output CK″ and D″. The SR-latch 344 operates to keep the data in the previous state when transiting from CK′=1/D′=1 to CK′=1/D′=0. The output D″′ from the SR-latch 344 in FIG. 9(d) can be combined with a previous clock signal, such as CK′ in FIG. 9 (a), as a pair of final data D and clock CK, respectively, corresponding to the same signals in FIG. 9(b), for further serial communication. There are many and equivalent embodiments of recovering clock and data from the quantizer output CK′ and D′ and they are all within the scope of this invention for those skilled in the art.

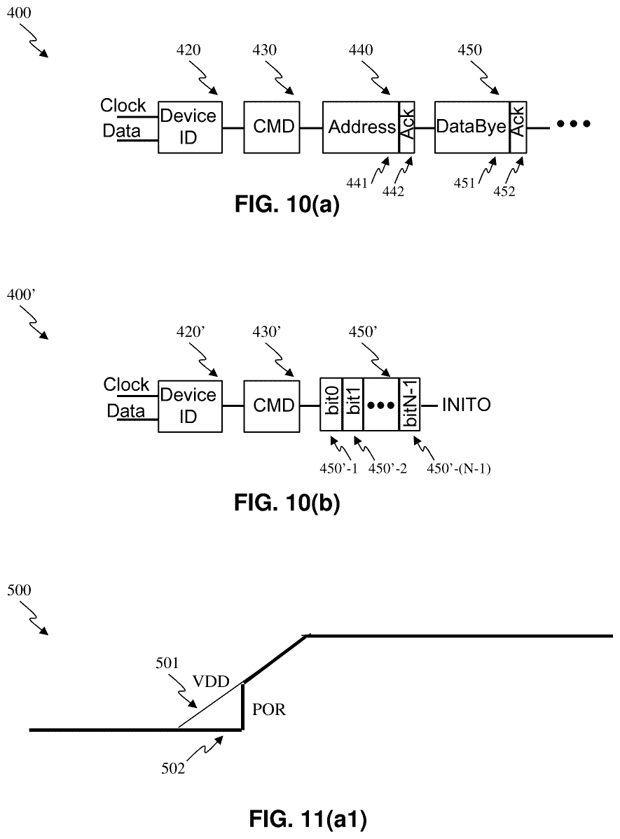

FIG. 10(a) shows a block diagram of a portion of a serial transmission frame 400 after obtaining proper clock and data signals from a 3-level CNTL. Device ID 420 specifies a target device to communicate. Command code CMD 430 specifies what kind of operations to do, such as read, program, soft program, or erase if applicable. If only a few of operations are available, the CMD 430 field can be combined with the pass code 209 as shown in FIG. 7 to issue more than one valid command signal in another embodiment. Then, an address field 440 can specify a starting address for the operation, which can include a byte of address bits 441 and an acknowledge bit 442. DataByte 450 field can specify the actual data to be programmed or soft programmed into the device (e.g., slave device) specified in Device ID 420. DataByte can include a byte of data 451 and followed by an acknowledge bit 452. Each field may have different bits in different embodiments. Address and databyte field can have any number of bits, such as 4, 8, or 16 bits. There can be a plurality of address bytes and databytes for communication. There can also be no acknowledge bit or more than one acknowledge bits from slave and/or master in other embodiments. Some of the fields, such as Device ID or CMD, can be omitted or combined with the other fields. There are many and equivalent embodiments of serial communication frames and they are within the scope of this invention for those skilled in the art.

FIG. 10(b) shows a portion of a simplified block diagram 400′ of a serial transmission frame after obtaining proper clock and data signals. Device ID 420′ specifies a target device to communication. Command code CMD 430′ is to specify the types of operations for communication, such as read, program, soft program, or erase if applicable. If only a few types of commands are available, the CMD 430′ field can be combined with the pass code 209 in FIG. 7 in another embodiment. The address field can be omitted and the communication starts from the first or the last bit after the programmable resistive memory is reset by POR or other signals. DataByte 450′ field, including bits 450′-1, 450′-2, . . . , 450′-(n−1), specifies the actual data to be programed or soft programmed into the device (e.g., slave device) specified in Device ID 420′. Some of the fields, such as Device ID or CMD, can be omitted or combined with the other fields. This simplified serial communication is more preferrable for small bit count, e.g. n=32˜256, short communication distance, and less noisy environments. After finishing operations on all the bits in a macro, an INITO (Initial Output), for example, can be generated to trigger the same operations for the next macros in a daisy chain manner. There are many and equivalent embodiments of simplified serial communication frames and they are within the scope of this invention for those skilled in the art.

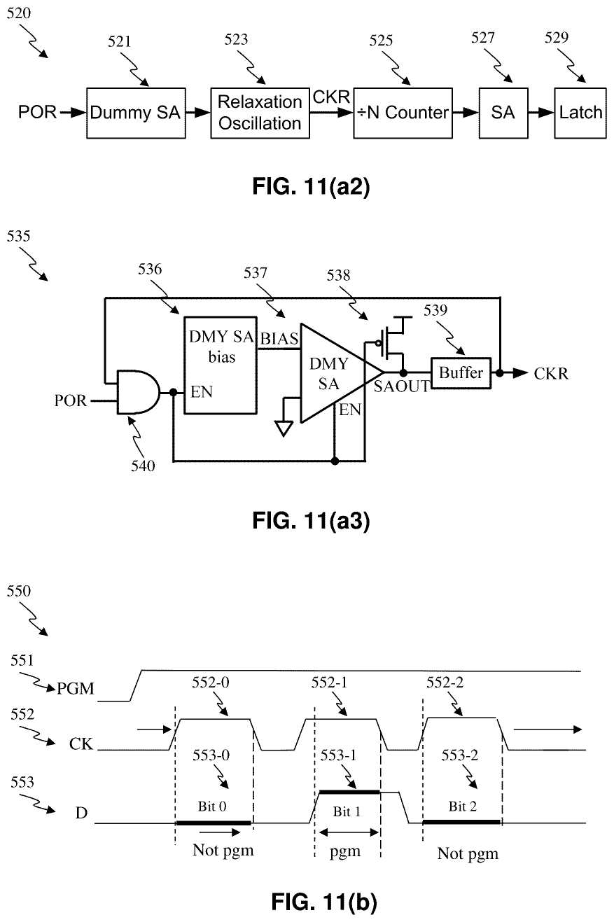

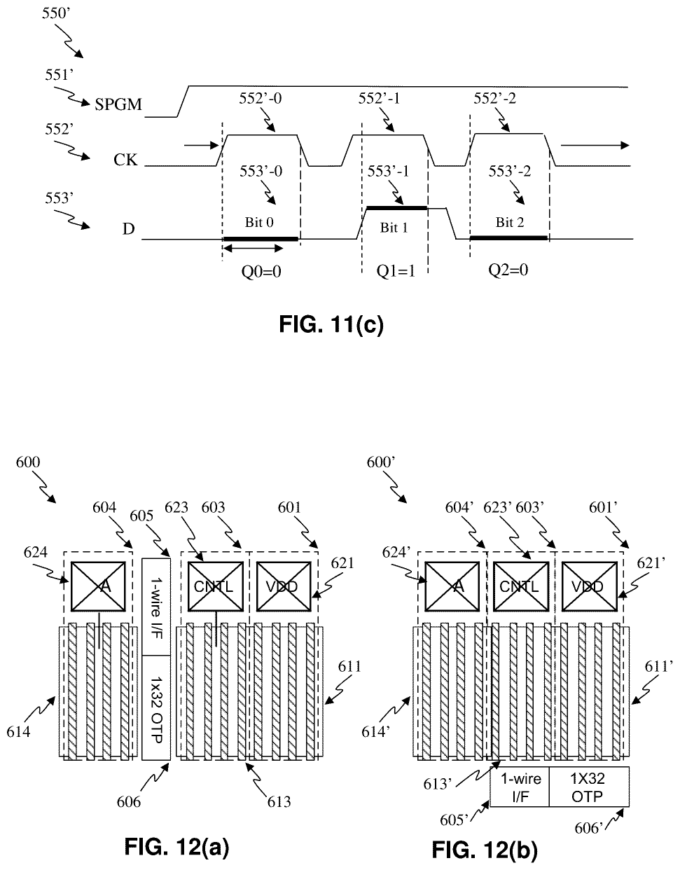

FIG. 11(a1) shows a timing waveform 500 of VDD 501 ramping to generate POR 502. When VDD 501 is ramping up from 0V to a final stable supply voltage, a Power-On-Reset signal can be generated after VDD 502 reaching a pre-determined value, 1.0˜1.5V for example. This POR 502 can be used to reset all latches, flip-flops and to start system initialization. The preferred POR signal 502 is to remain at 0V until VDD reaches a pre-determined level and then rises sharply.

FIG. 11(a2) shows a block diagram 520 for a portion of reading data into respective latches, after a POR signal is generated as 502 in FIG. 11(a1). The POR can be used as INIT in FIG. 5(b) to start reading data into latches. POR can enable a dummy sense amplifier (SA) 521. This dummy SA has a turn-on threshold that are higher than the normal SA. For example, if the normal SA's read 0 and read 1 threshold are 100 ohm and 4K ohm respectively and reference resistance is 1.5K. Further, if reading 1 is faster than reading 0, the dummy SA can have an SA with the same reference resistance 1.5K to sense a replica cell with cell resistance 600 ohm. This can ensure that the normal SA can work if the dummy SA works. Relaxation oscillation block 523 can be enabled by the output of dummy SA to generate a read clock (CKR). The read clock can be used to start an N-bit counter 525 to generate read addresses. Then, the read addresses can be used to select any of the programmable resistive cells to read in the SA block 527 one by one, Finally, the read data are stored into their own latch in latch block 529. After reading the last bits and the counter reaching 2^{N}−1, INITO, as shown in FIG. 5(b), can be asserted to trigger reading the next programmable resistive memory. The operations in FIGS. 11 (a1) and 11 (a2) depend on VDD ramping only and is not related to the 3-level signal CNTL.

FIG. 11(a3) shows a portion of a block diagram of a relaxation oscillator 535, corresponding to relaxation oscillation 523 in FIG. 11(a2), according to one embodiment. The relaxation oscillation 535 has a dummy SA bias 536 to generate a Bias for a dummy SA 537, which has a device 538 to pull up the SA output high after the dummy SA 537 is disabled. The dummy SA 537 output SAOUT can be an input to a delay buffer 539, whose output is a read clock CKR. The dummy SA 536 can be enabled by ANDing POR and CKR. The POR and CKR are correspond to the same signals noted in FIG. 11(a1) or 11(a2). When the POR is low, the output of the AND 540 is low to disable the dummy SA bias 536 and the dummy SA 537 so that the SA output SAOUT is high. When the POR is high, the AND 540 output EN is high, the dummy SA bias 536 generates a Bias signal to turn on the dummy SA 537 to sense data and to set SAOUT low. After some delay in the buffer 539, the CKR sets EN low in the output of the AND 540. Once EN is low, the dummy SA 537 output SAOUT will be pulled high again to assert AND 540 output and to turn on the dummy SA bias 536 and the dummy SA 537 to trigger another round of operation. This procedure can go on and on to generate a read clock CKR.

FIG. 11(b) shows a portion of a timing waveform 550 of a programming operation, according to one embodiment. The program timing waveform 550 includes PGM 551, CK 552, and D 553. The clock CK 552 has the first 3 cycles labelled as 552-0, 552-1, and 552-2, respectively. Similarly, the data D 553 has the first 3 cycles labelled as 553-0, 553-1, and 552-2, respectively. Each clock CK corresponds to an access cycle selected by a bit address sequentially. If the data D is high during the clock CK high period, the selected bit will be programmed, otherwise nothing happens. The addresses can also be selected randomly in other embodiments. Proper data D and address setup and hold time to clock need to be satisfied to ensure correct operations.

FIG. 11(c) shows a portion of a timing waveform 550′ of a soft programming, according to one embodiment. The soft program timing waveform includes SPGM 551′, CK 552′, and D 553′. The clock CK 552′ has the first 3 cycles labelled as 552′-0, 552′-1, and 552′-2, respectively. Similarly, the data D 553′ has the first 3 cycles labelled as 553′-0, 553′-1, and 553′-2, respectively. Each clock CK corresponds to an access cycle selected by a bit address sequentially. During the clock CK high period, the selected bit will be loaded with data D. The addresses can also be selected randomly in other embodiments. Proper data D and address setup and hold time to clock need to be satisfied to ensure correct operations.

FIG. 12(a) shows a portion of a layout 600 for a low-bit-count programmable resistive memory 606 and a 1-wire interface block 605 fitting into an I/O pad structure 600, according to one embodiment. Layout block 600 has a VDD I/O pad 601 that includes a pad 621 and an ESD structure 611, a CNTL I/O pad 603 that includes a pad 623 and an ESD structure 613, and another adjacent pad A 604 that includes a pad 624 and an ESD structure 614. There can be also one or more instances of low-bit-count programmable resistive memory (not shown) using the same 1-wire interface block 605 placed between CNTL pad 603 and the pad A 604. The CNTL pad 603, programmable resistive memory 606, and 1-wire block 605 can all fit into the I/O library structures, including form factors such as width or height of a I/O cells, metal scheme such as number of metal layers and metal bus width, and power/ground busing, such as bus direction, metal layers, and metal width, etc.

FIG. 12(b) shows a portion of a layout 600′ for a low-bit-count programmable resistive memory 606′ and a 1-wire interface block 605′ fitting into an I/O pad structure 600′, according to one embodiment. Layout block 600′ has a VDD I/O pad 601′ that includes a pad 621′ and an ESD structure 611′, a CNTL I/O pad 603′ that includes a pad 623′ and an ESD structure 613′, and another adjacent pad A 604′ that includes a pad 624′ and an ESD structure 614′. There can be also one or more instances of low-bit-count programmable resistive memory (not shown) using the same 1-wire interface block 605′ placed in the bottom of CNTL pad 603′ and the VDD pad 601′. The CNTL pad 603′, programmable resistive memory 606′, and 1-wire block 605′ can fit into the I/O library structures, including formfactors such as width or height of a I/O cells, metal scheme such as number of metal layers and metal bus width, and power/ground busing, such as bus direction, metal layers, and metal width, etc.

The placement of programmable resistive memory 606 or 606′ and 1-wire interface block 605 or 605′ in FIG. 12 (a) or 12 (b), respectively, are for illustrative purposes. They can be placed between pads, on top or bottom of any other pads, or in some empty area in an I/O pad structure 600 or 600′ in FIG. 12 (a) or 12 (b), respectively. In some cases that CUP, Circuit Under Pad, technologies are available, the whole or a part of the programmable resistive memory 606 or 606′ and 1-wire interface block 605 or 605′ in FIG. 12(a) or 12(b), respectively, can be placed under the bonding pads to further reduce area.

The layout of the programmable resistive memory block 600 and 600′ includes at least one programmable resistive memory 606 and 606′ and the associated 1-wire interface blocks 605 and 605′ as shown in FIGS. 12(a)(b), respectively, are small in size, requires either core or I/O VDD voltage to operate, needs no high voltage circuits, such as charge pumps or analog switches, and needs no special layout restrictions except non-waivable by design rules that can fit into any standard I/O library. Therefore, the programmable resistive memory and the 1-wire interface can be merged as part of an I/O library and using automated logic synthesis flow to generate low-bit-count programmable resistive memory. Furthermore, the pad CNTL 603 or 603′ in FIG. 12(a) or 12(b) can be used for any other signal that uses analog I/O pad, i.e. an I/O pad that can pass through any analog signals without any MOS or Boolean gates in between.

FIGS. 5(a)-12 (b) only show a few of many possible embodiments of a low-bit-count programmable resistive memory block. The number of programmable resistive cells can vary, though more likely to be 1 to 256 bits and cascadable. The programmable resistive cells can be organized in a one or two dimensional array or in shift register configurations physically. The number of rows or columns may vary. The data access can be random, sequential, or through shift registers by one bit or a group of bits at a time. The selector in a programmable resistive cell can be a MOS, diode including junction or Schottky diode, bipolar device, or any other active devices. There can be a single or a plurality of sense amplifiers to sense a single or a plurality of cells simultaneously. The sense amplifiers can be activated more than once to sense one or more bits by a POR signal or by a signal generated from internal or external of the low-bit-count programmable resistive memory. The actual programming time can be during the CLK low period rather than the high period. There are many variations and equivalent embodiments for the low-bit-count programmable resistive memory and 1- wire interface designs and layouts and they are all within the scope of this invention for those skilled in the art.

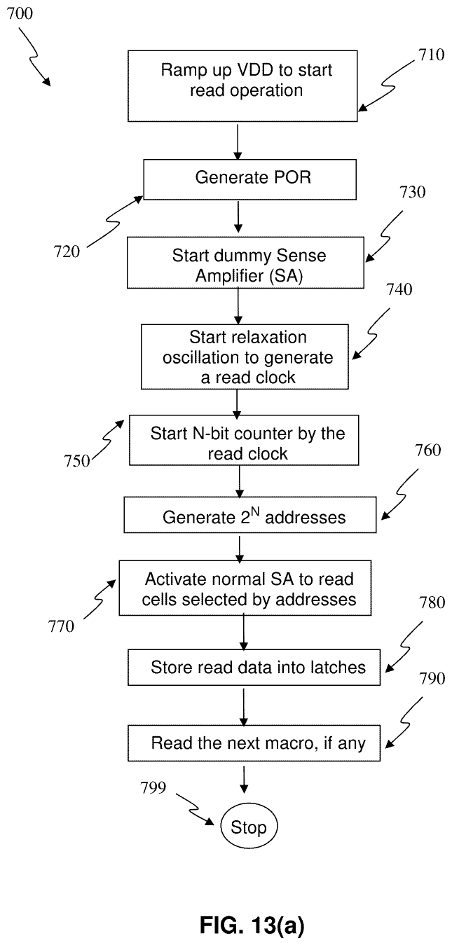

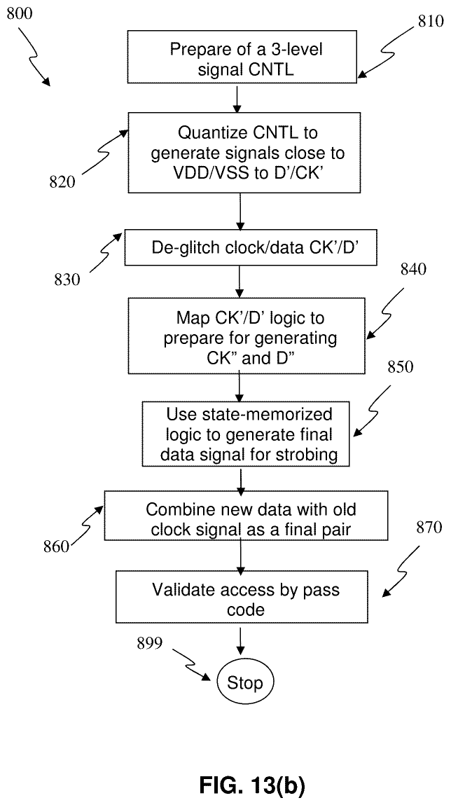

FIG. 13(a) shows a flow chart of a read procedure 700 for a low-bit-count programmable resistive memory, such as corresponding to FIG. 11(a1) or 11(a2), according to one embodiment. The read procedure 700 starts by ramping up a supply voltages VDD in step 710, and then generating a POR, Power-On Reset, when the VDD reaches to a pre-determined voltage level in step 720. The POR turns on a dummy sense amplifier (SA) in step 730. The dummy SA can start to work once POR is on or wait until VDD reaches to a higher voltage level. In any cases, if dummy SA can perform read properly, the normal SA can read data successfully. The dummy SA starts a relaxation oscillator to generate a read clock based the dummy SA sensing time with some delays in step 740. The read clock can start an N-bit counter in step 750 and to generate 2^{N} addresses in step 760. Then at least one normal SA can be activated to read data in the selected cells by the addresses generated in step 770 and to store read data into latches in step 780. After finishing reading all 2^{N} addresses, an INITO, as shown in FIG. 5(b), can be asserted to read a next programmable resistive memory in step 790. If all programmable resistive memories have been read, the read procedure 700 can stop at step 799.

FIG. 13(b) shows a flow chart of a recovery procedure 800 to recover clock and data from a 3-level one-wire CNTL for a low-bit-count programmable resistive memory, such as corresponding to FIGS. 5(a) through 9(d), according to one embodiment. The recovery procedure 800 starts by preparing a 3-level signal CNTL in step 810. Then, quantizing the CNTL into signals with thresholds close to VDD and VSS (0V) to generate a raw data and clock signals, respectively, in step 820. The raw clock and data go through de-glitch circuits in step 830 to filter any glitches and to improve noise immunity. Next, the raw clock and data generated in step 820 and after de-glitch processing can go through a logic mapping in step 840 and then to a state-memorized logic, such as a SR-latch, in step 850 to generate a final data D. The final data D and a clock generated previously can be paired in step 860 for further serial communication. The final clock and data can go through a pass code validation 870 to validate a proper access, since the 1-wire communication can be very noisy. The pass code can be a one-or two-dimensional plurality of bits of alternated data, such as 4-7 bits (e.g., 1010101 or 0101010). After proper clock and data are generated and access is validated, the preparation of serial interface can stop in step 899 and at least one of the serial communication frames, such as in FIG. 10(a) or 10(b), can start.

The above discussions are for illustrative purposes. The block diagram of the programmable resistive memory shown in FIGS. 5(a) and 5(b) is only a few of many possible embodiments. The supply voltage VDD and program supply voltage VDDP can be the same or different in different embodiments. The block diagrams in FIG. 6 through FIG. 9(d) to recover proper clock and data signals from a 3-level signal are for illustrative purposes. There are many variations and yet equivalent methods, logic, and circuit embodiments to recover clock and data for serial communication from a 3-level signal CNTL. The quantizer can be any Boolean gates or an analog comparator. The de-glitch circuits can be any kinds of delay elements with different combination of Boolean logic. The logic mapping and state-memorized logic can be implemented in different forms of circuits or logic according to different embodiments. The dummy and normal sense amplifiers in FIG. 11(a2) can be static SA, such as cascode or current mirrored type, or can be dynamic SA that counts on high-gain region of a latch to sense resistance difference in a programmable resistive cell. The sensing can be one bit or many bits at a time. The number of SAs can vary in different embodiments. Similarly, the layout of the programmable resistive memory and 1-wire interface in FIGS. 12(a) and 12(b) can have different sizes, placements, mirroring, or orientation in different embodiments. In another embodiment, the programmable resistive memory and 1-wire interface block can have all or a portion of the layout placed under I/O pad, in a so-called CUP, Circuit Under Pad, technology to further reduce the footprint. Similarly, the procedures described in FIGS. 13(a)(b) are for exemplifying purposes. The detailed implementation in the procedures may vary. For example, some steps may be omitted. Some steps can be re-arranged in different orders. There can be many embodiments of the layout, circuit, logic, architecture, methods, and procedures and that they are still within the scope of this invention for those skilled in the art.

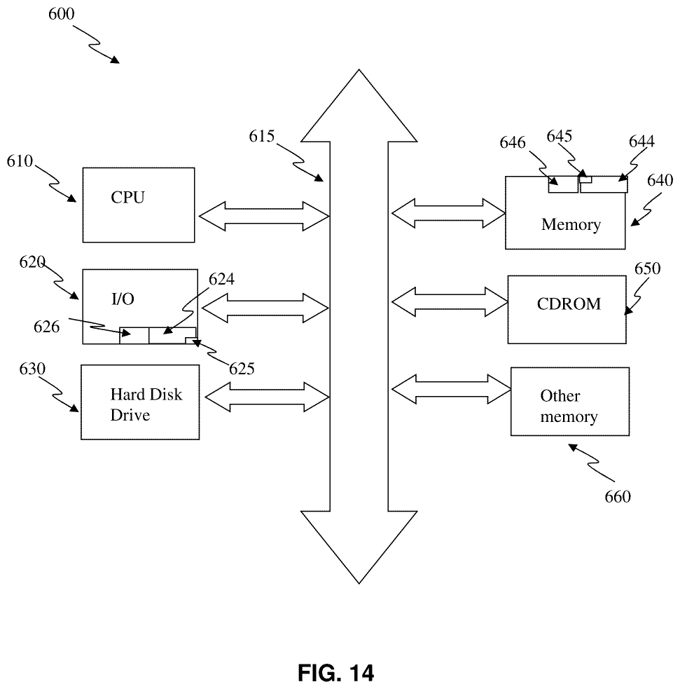

FIG. 14 shows a processor electronic system 600 that employs at least one low-bit-count programmable resistive memory and a 1-wire serial interface block, according to one embodiment. The processor electronic system 600 can include at least one programmable resistive cell 645, such as in a cell array 644, in a programmable resistive memory block 640 that contains at least one 1-wire interface 646, according to one embodiment. Similarly, the processor electronic system 600 can include at least one programmable resistive cell 625, such as in a programmable resistive memory 624, with a 1-wire interface 626 in an I/O block 620, according to another embodiment. The processor electronic system 600 can, for example, pertain to an electronic system. The electronic system can include a Central Process Unit (CPU) 610, which communicate through a common bus 615 to various memory and peripheral devices such as the I/O block 620, hard disk drive 630, CDROM 650, the programmable resistive memory block 640, and other memory 660. Other memory 660 is a conventional memory such as SRAM, DRAM, or flash, typically interfaces to CPU 610 through a memory controller. CPU 610 generally is a microprocessor, a digital signal processor, or other programmable digital logic devices. The programmable resistive memory block 640, the programmable resistive memory 624, and/or the 1-wire interface 646 and 626 is preferably constructed as an integrated circuit, which includes at least one memory array having at least one programmable resistive cell 645 or 625. The programmable resistive memory block 640 typically interfaces to the CPU 610 or any other logic blocks in the processor electronic system 600 through a simple bus or 1-wire serial interface 646 or 626, respectively. Similarly, the programmable resistive memory 624 located in the I/O block 620 can interface to the CPU 610 or external circuits through a 1-wire serial interface 626. If desired, the memory block 640 or the programmable resistive memory 624 and/or the 1-wire serial interface 646 or 626 may be combined with the processor, for example the CPU 610, in a single integrated circuit.

The programmable resistive memory as described herein can, for example, include a plurality of programmable resistive memory cells in an integrated circuit, and the at least one of the cells can include at least: a programmable resistive element (PRE) having one end coupled to a first supply voltage line; a selector having at least a first active region and a second active region, where the first active region having a first type of dopant or substantially intrinsic semiconductor and a second active region having a first or a second type of dopant, the first active region providing a first terminal of the selector, the second active region providing a second terminal of the selector, both the first and second active regions built by semiconductor material on a semiconductor, or insulator substrate, the first active region coupled to the PRE and the second active region coupled to a second supply voltage line; and a gate fabricated on the layer of semiconductor or metal material with a sandwich of dielectric in between configured to divide the first and the second active regions; the gate coupled to a third supply voltage line. The PRE can be configured to be programmable by applying voltages to the first, second, and/or the third supply voltage lines to thereby change its logic state with the control signals provided by a 3-level 1-wire serial communication signal.

The invention can be implemented in a part or all of an integrated circuit in a Printed Circuit Board (PCB), or in a system. The low-bit-count programmable resistive memory can be an OTP (One-Time Programmable), FTP (Few-Time Programmable), MTP (Multiple-Time Programmable), Charge-storing (floating-gate) nonvolatile memory, or emerging nonvolatile memory. The OTP can be fuse or anti-fuse, depending on the initial resistance state being low or high, respectively, and the final resistance is just the opposite. The fuse can include at least one of the silicided or non-silicided polysilicon, local interconnect, metal, metal alloy, metal-gate, polymetal, thermally isolated semiconductor, such as SOI (Silicon On Isolator), tall and slim fin structure in FinFET, or silicon rod or sheet in GAA (Gate All Around) technologies, etc. The OTP can also be a contact or via fuse by applying high current to breakdown contact or via. The anti-fuse can be a gate-oxide breakdown anti-fuse, contact or via anti-fuse with dielectrics in-between. The charge-storing nonvolatile memory can be EPROM, EEPROM, or flash memory. The emerging nonvolatile memory can be Magnetic RAM (MRAM), Phase Change Memory (PCM), Conductive Bridge RAM (CBRAM), Ferroelectric RAM (FRAM), or Resistive RAM (RRAM). Though the program mechanisms are different, their logic states can be distinguished by different resistance values.

The above description and drawings are only to be considered illustrative of exemplary embodiments, which achieve the features and advantages of the present invention. Modifications and substitutions of specific process conditions and structures can be made without departing from the spirit and scope of the present invention.

The many features and advantages of the present invention are apparent from the written description and, thus, it is intended by the appended claims to cover all such features and advantages of the invention. Further, since numerous modifications and changes will readily occur to those skilled in the art, it is not desired to limit the invention to the exact construction and operation as illustrated and described. Hence, all suitable modifications and equivalents may be resorted to as falling within the scope of the invention.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A programmable resistive memory integrated in an integrated circuit, the programmable resistive memory comprising:
at least one 1-wire serial interface block; and
at least one programmable resistive memory block, the at least one programmable resistive memory block including at least: a plurality of programmable resistive cells, at least one of the plurality of programmable resistive cells including at least:
a programmable resistive element (PRE) having one end coupled to a first supply voltage line;
a selector having at least a first active region and a second active region, the first active region having a first type of dopant and a second active region having the first type or a second type of dopant, the first active region providing a first terminal of the selector, the second active region providing a second terminal of the selector, both the first and second active regions built on a semiconductor material or insulator substrate, the first active region coupled to the programmable resistive and the second active region coupled to a second supply voltage line; and
a gate fabricated on the layer of the semiconductor or metal material with a sandwich of dielectric in between configured to divide into the first and the second active regions, the gate coupled to a third supply voltage line,
wherein the PRE is configured to be programmable by applying voltages to the first, second, and/or the third supply voltage lines to thereby change its logic state with the control signals generated from the 1-wire serial interface block.

2. The programmable resistive memory as recited in claim 1, wherein the 1-wire serial interface block has a 1-wire signal CNTL that a 1-wire signal CNTL that has three distinct logic levels to generate at least clock and data signals for serial communication.

3. The programmable resistive memory as recited in claim 2, wherein the 1-wire signal CNTL includes circuit blocks configured to provide at least: quantization, de-glitch, logic mapping, and state-memorized logic.

4. The programmable resistive memory as recited in claim 3, wherein the quantization circuit block uses a plurality of thresholds that are (i) approximately at VDD or VSS, or (ii) approximately at VDD-|Vtp| or Vtn.

5. The programmable resistive memory as recited in claim 3, wherein the de-glitch circuit block filters out any glitches in the clock and data signals.

6. The programmable resistive memory as recited in claim 3, wherein the logic mapping circuit bock and the state-memorized logic circuit block processes the clock signal and/or the data signals to extend a falling edge of the data signal beyond a falling edge of the clock signal.

7. The programmable resistive memory as recited in claim 3, wherein the pass code block detects special codes to validate an access.

8. The programmable resistive memory as recited in claim 3, wherein reading the at least one of the programmable resistive cell is by generating a Power-On-Reset (POR) and going through at least one of the following circuit blocks: (a) starting at least one dummy sense amplifier (SA), (b) starting a relaxation oscillation to generate a read clock, (c) starting a counter by the read clock, (d) generating addresses from the counter output, (e) activating at least one of the normal SA to read data from one or a plurality of cells and to store the data into latches, and (f) generating a finish signal to activate the next programmable resistive memory.

9. A programmable resistive memory as recited in claim 1, wherein the programmable resistive memory is an One-Time Programmable memory.

10. A programmable resistive memory as recited in claim 9, wherein the OTP element comprises at least one of the following: a polysilicon, silicided polysilicon, metal, local interconnect, metal gate, or thermally insulated semiconductor region, such as SOI (Silicon On Insulator), silicon fin in FinFET, or silicon rod or sheet in GAA (Gate All Around) structures.

11. A programmable resistive memory as recited in claim 1, wherein the programmable resistive memory is a low-bit-count memory having a data storage capacity of less than 256 bits, and wherein the integrated circuit has a plurality of bonding pads, and wherein at least a portion of the programmable resistive memory is positioned under the bonding pads.

12. An electronics system, comprising:
a processor; and
at least one programmable resistive memory that includes at least:
at least one 1-wire serial interface block; and
at least one programmable resistive memory block, the programmable resistive memory block operatively connected to the processor, the programmable resistive memory block including at least a plurality of programmable resistive cells, at least one of the plurality of programmable resistive cells including at least:
a programmable resistive element (PRE) having one end coupled to a first supply voltage line;
a selector having at least a first active region and a second active region, the first active region providing a first terminal of the selector, the second active region providing a second terminal of the selector, the first active region coupled to the PRE and the second active region coupled to a second supply voltage line; and
a gate configured to divide into the first active region and the second active region, the gate coupled to a third supply voltage line,
wherein the PRE is configured to be programmable by applying voltages to the first, second, and/or the third supply voltage lines to thereby change its logic state with the control signals generated from the 1-wire serial interface block.

13. The electronics system as recited in claim 12, wherein the 1-wire serial interface block has a 1-wire signal CNTL that has three distinct logic levels to generate at least clock and data signals for serial communication.

14. The electronics system as recited in claim 12, wherein the 1-wire serial interface block includes circuit blocks configured to provide at least: quantization, de-glitch, logic mapping, and state-memorized logic.

15. The electronics system as recited in claim 12, wherein the quantization circuit block generates clock and data signals from the 1-wire signal CNTL based on predetermined thresholds.

16. The electronics system as recited in claim 12, wherein the de-glitch circuit block comprises a delay circuit and/or one or more Boolean gates to filter out any glitches in the clock and data signals.

17. The electronics system as recited in claim 12, wherein the logic mapping circuit block and the state-memorized logic circuit block process the data signals to extend the data falling edge beyond the clock falling by using some Boolean logic in the logic mapping circuit block and by using at least one latch in the state-memorized logic circuit block.

18. The electronics system as recited in claim 12, wherein the 1-wire serial interface further includes a pass code circuit block, and wherein the pass code block detects special codes to validate an access.

19. The electronics system as recited in claim 12, wherein reading the at least one of the programmable resistive cell is by generating a Power-On-Reset (POR) and performing at least one of the following: (a) starting at least one dummy sense amplifier (SA), (b) starting a relaxation oscillation to generate a read clock, (c) starting a counter by read clock, (d) generating addresses from the counter output, (e) activating at least one of normal SA to read data from one or a plurality of the programmable resistive cells and to store the read data into latches, and (f) generating a finish signal to activate the next programmable resistive memory.

20. The electronics system as recited in claim 12, wherein the programmable resistive memory is integrated as part of an I/O library in layout, circuit, and logic and generated with the other cells in the I/O library.

21. The electronics system as recited in claim 12, wherein at least a portion of the programmable resistive memory is placed under bonding pads.

22. The electronics system as recited in claim 12, wherein the programmable resistive memory is a low-bit-count memory having a data storage capacity of less than 256 bits.

23. A method for providing a 1-wire interface to recover clock and data signals for at least one programmable resistive memory in an integrated circuit, the method comprises:
receiving a 3-level control signal;
converting the 3-level control signal into determine clock and data signals based on first and second thresholds, respectively;
filtering out noise from the determined clock and data signals;
modifying the determined clock signal or the determined data signal to apply a state-memorized effect; and
subsequently using the determined clock signal and the determined clock signal for serial communication.

24. The method as recited in claim 23, wherein the 3-level control signal has its three levels at based on (i) approximately full (100%), half (50%), and 0 Volts of an I/O or core voltage, or (ii) approximately full (100%) of IO voltage, full (100%) of core voltage, and 0 Volts.

25. The method as recited in claim 23, wherein the programmable resistive memory and the 1-wire interface are integrated with an I/O library in layout, circuit, and logic designs, and are generated by using the same design flow as using the I/O library.

26. The method as recited in claim 23, wherein the programmable resistive memory is a low-bit-count memory having a data storage capacity of less than 128 bits.
